(19) United States
(12) Patent Application Publication
(10) Pub. No.: US 2008/0003716 A1
(43) Pub. Date: Jan. 3, 2008

(54) Semiconductor device and method of manufacturing the semiconductor device

(75) Inventor: Seiichi Takahashi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/819,975

(22) Filed: Jun. 29, 2007

(30) Foreign Application Priority Data
Jul. 3, 2006 (JP) 2006-183743

(51) Int. Cl. H01L 21/58

(52) U.S. Cl. 438/108; 438/126

(57) ABSTRACT

A semiconductor device according to an embodiment of the present invention includes: a silicon wafer; a redistribution layer formed on the silicon wafer and including a plurality of pads to be connected with a solder bump and a plurality of redistribution lines to be connected with the pads, the pads being exposed at an upper surface; and a semiconductor chip placed in an opening which is formed through the silicon wafer and to which a rear surface as the opposite surface to the pads of the redistribution layer is exposed, and connected to the redistribution lines (lands) exposed to the opening.

### BACKGROUND OF THE INVENTION

1. Field of the Invention

The present invention relates to a semiconductor device and a method of manufacturing the semiconductor device.

2. Description of Related Art

Chip size packages (CSPs) that redistribute a fine pad on a chip to a coarser plane-array pad using an intermediate material to enable flip chip bonding are compact and slim compared with the other packages. Among those, a so-called wafer level CSP (hereinafter referred to as “W-CSP”) is manufactured in such a manner that a redistribution layer is directly formed on a semiconductor wafer and diced into chips. Since wire bonding is not used, the W-CSP is the smallest and slimmest in the CSPs, and has outstanding characteristics such as an ability to suppress a parasitic inductance and high heat conductivity.

Japanese Unexamined Patent Application Publication No. 2003-309215 discloses a technique of forming a redistribution layer for flip chip bonding. According to this technique, a supporting substrate having high rigidity and flatness is prepared, and an etch back layer is formed on the substrate surface. Then, a redistribution layer is formed thereon, followed by bonding a reinforcing frame made of stainless steel or the like thereto. After that, the etch back layer is removed by wet etching to separate the redistribution layer from the supporting substrate to package the semiconductor chip into the reinforcing frame to thereby complete a W-CSP.

FIG. 5 is a sectional view of a W-CSP of the related art different from Japanese Unexamined Patent Application Publication No. 2003-309215. A silicon substrate has a first region 301 and a second region 302. An integrated circuit (not shown) and a plurality of fine pads with a fine pitch are formed in the first region 301. A redistribution layer 303 including a plurality of solder bumps with a rougher pitch is formed on both of the first region 301 and the second region 302. The second region 302 formed around the first region 301 is necessary to manufacture a W-CSP. The redistribution layer 303 redistributes the fine pads with the fine pitch of the first region 301 to the solder bumps with a rougher pitch rougher than the fine pitch. The solder bumps of the redistribution layer 303 enable flip chip bonding.

Incidentally, techniques related to another redistribution layer technique different from the W-CPS shown in FIG. 5 are disclosed in Japanese Unexamined Patent Application Publication No. 2003-309215 and in addition, Japanese Unexamined Patent Application Publication Nos. 2003-31724 and 2006-19433.

The W-CSP of FIG. 5 causes a serious problem if the number of pins is large although an actual active region is small. That is, a chip area corresponding to the arrayed pins is required.

It is not an exaggeration to say that a pin pitch in packaging an LSI to a mounting board, which is specified by a set maker is almost not reduced as compared with finer design rule of a wafer manufacturing process. Under current conditions, the pin pitch is about 0.4 to 0.65 mm. Even if pins are arrayed with 0.5 mm pitches in full grid, a chip area of about 3 mm square is necessary for 36 pins, a chip area of about 3.5 mm square is necessary for 49 pins, and a chip area of about 4 mm square is necessary for 64 pins. If an area of a region (first region 301) comprising an active region, which includes transistors etc., and a peripheral region, which includes a bonding pad etc., is smaller than the above area, a free region wasted to array the pins (second region 302) exists on the chip.

Thus, as the number of pins increases in the W-CSP, a chip area increases and a yield per wafer is decreases. Hence, a manufacturing cost per chip, which is calculated by dividing the manufacturing cost per wafer by the yield is increased in proportion to the number of pins.

In the case of encapsulating with the above redistribution layer technique disclosed in Japanese Unexamined Patent Application Publication Nos. 2003-309215, 2003-31724 and 2006-19433, a chip area is the sum of an area of the active region and an area of the peripheral region, and an increase in the number of pins or the function of circuit is cancelled by a fine patterning process. However, in the case of manufacturing a W-CSP with multiple pins, the waste second region 302 having no element is formed as described above. In addition, the second region 302 undergoes each manufacturing step, resulting in cost increase.

Such tendency becomes conspicuous since an active region is reduced as the wafer manufacturing process proceeds towards a fine patterning process. Therefore, production of the multipin type W-CSP with a semiconductor chip manufactured with the advanced process costs high.

On the other hand, in a BGA (ball-grid array) or LGA (land-grid array) package, a chip to encapsulate includes only an active region and a peripheral region. Therefore, a manufacturing cost per chip can be minimized. However, a manufacturing process for packaging is not included in wafer fabrication process of a chip. Thus, it is necessary to prepare a production line dedicated to packaging or outsource the process to a subcontractor. Further, a substrate or other such materials are required. The above costs are added to a unit price of a product, resulting in high costs.

From this point of view, the technique as disclosed in Japanese Unexamined Patent Application Publication No. 2003-309215 might be one solution to the above problems. That is, in the technique of Japanese Unexamined Patent Application Publication No. 2003-309215, a semiconductor chip including an active region and a peripheral region, and a redistribution layer including a solder bump for flip chip bonding are formed in different steps, and then the redistribution layer is connected to the semiconductor chip. However, this technique requires a supporting substrate having high rigidity and flatness and a reinforcing frame made of stainless steel or the like. Moreover, it is necessary to execute a step of bonding the redistribution layer to the reinforcing frame with an insulation adhesive and a step for etch back to separate the supporting substrate from the redistribution layer. These steps cannot be incorporated in a manufacturing process of the semiconductor wafer. Therefore, another production line is necessary, resulting in cost increase.

### SUMMARY

According to an aspect of the present invention, a method of manufacturing a semiconductor device including a semiconductor chip, includes: forming a redistribution layer including a plurality of pads to be connected with an external electrode terminal and a plurality of redistribution lines to be connected with the pads on a silicon wafer, the pads being exposed; removing a predetermined portion of the silicon wafer to expose the redistribution lines at the opposite surface to the pads of the redistribution layer; placing the semiconductor chip in a space formed by removing the predetermined portion of the silicon wafer; and connecting the semiconductor chip to the redistribution lines exposed at the opposite surface.

According to another aspect of the present invention, a method of manufacturing a semiconductor device including a semiconductor chip, includes: forming a redistribution layer including a plurality of pads to be connected with an external electrode terminal and a plurality of redistribution lines to be connected with the pads on a silicon wafer, the redistribution lines being exposed; connecting the semiconductor chip to the redistribution lines; and removing the silicon wafer to expose the pads at the opposite surface to the redistribution lines of the redistribution layer.

Further, a semiconductor device according to another aspect of the present invention includes: a silicon wafer; a redistribution layer formed on the silicon wafer and including a plurality of pads to be connected with an external electrode terminal and a plurality of redistribution lines to be connected with the pads, the pads being exposed at an upper surface; a semiconductor chip placed in an opening which is formed through the silicon wafer and to which a rear surface as the opposite surface to the pads of the redistribution layer is exposed, and connected to the redistribution lines exposed to the opening.

A semiconductor device according to another aspect of the present invention include: a redistribution layer including a plurality of pads to be connected with an external electrode terminal and a plurality of redistribution lines to be connected with the pads, the pads being exposed at an upper surface; a semiconductor chip connected to the redistribution lines at a rear surface as the opposite surface to the pads of the redistribution layer; and a supporting substrate which is provided on the rear surface of the redistribution layer and to which the semiconductor chip is embedded.

According to the present invention, a redistribution layer can be obtained not through wafer fabrication process for forming the active region. Thus, the device can be manufactured at lower cost than that of existing W-CSPs. Further, the device can be manufactured with a general silicon wafer production line alone, so any special supporting substrate or reinforcing frame is unnecessary. This contributes to further reduction in manufacturing cost. Thus, a semiconductor device and a method of manufacturing the semiconductor device, which can save a manufacturing cost, are realized.

According to the present invention, it is possible to provide a semiconductor device and a method of manufacturing the semiconductor device, which can save a manufacturing cost.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view of a semiconductor device according to a first embodiment of the present invention;

FIGS. 2A and 2B are sectional views for illustrating a method of manufacturing the semiconductor device according to the first embodiment of the present invention;

FIG. 3 is a sectional view of a semiconductor device according to a second embodiment of the present invention;

FIGS. 4A and 4B are sectional views for illustrating a method of manufacturing the semiconductor device according to the second embodiment of the present invention; and

FIG. 5 is a sectional view of a semiconductor device of the related art.

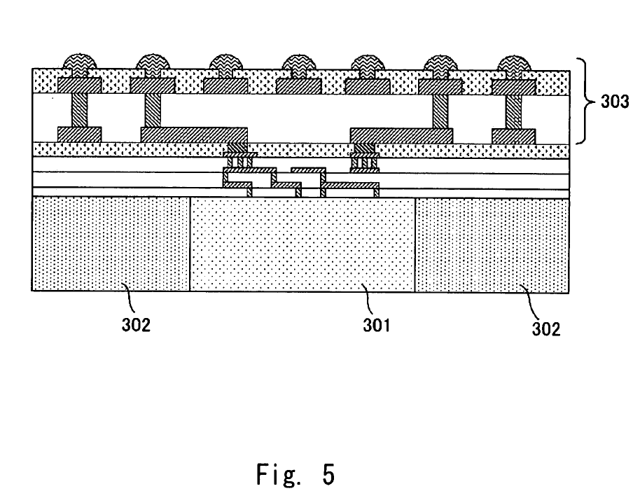

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, preferred embodiments of a semiconductor device and a method of manufacturing the semiconductor device according to the present invention will be described in detail with reference to the accompanying drawings. Incidentally, the same components are denoted by identical reference numerals throughout the accompanying drawings and repetitive description thereof is omitted here.

### First Embodiment

A semiconductor device according to a first embodiment of the present invention comprises: a silicon wafer; a redistribution layer formed on the silicon wafer and including a plurality of pads to be connected with an external electrode terminal and a plurality of redistribution lines to be connected with the pads, the pads being exposed at an upper surface; and a semiconductor chip placed in an opening which is formed through the silicon wafer and to which a rear surface as the opposite surface to the pads of the redistribution layer is exposed, and connected to the redistribution lines exposed to the opening.

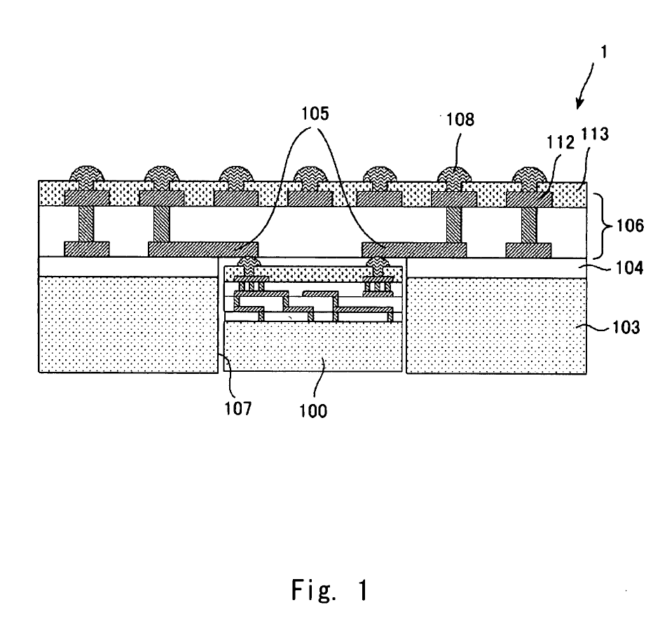

FIG. 1 is a sectional view of a semiconductor device according to a first embodiment of the present invention. The semiconductor device 1 includes a silicon wafer 103, a redistribution layer 106, an opening 107, and a semiconductor chip 100. The redistribution layer 106 is formed on the silicon wafer 103, and pads 112 to be connected with solder bumps 108 are exposed at the upper surface of the redistribution layer 106. A redistribution line to be connected with the pad 112 is formed in the redistribution layer 106. The opening 107 is formed in the silicon wafer 103 and passes through the silicon wafer 103. The semiconductor chip 100 is placed in the opening 107, and connected to the redistribution line (land 105) exposed at the rear surface of the redistribution layer 106.

The redistribution layer 106 is formed on the silicon wafer 103 with an insulating film 104 preferably an oxide film interposed therebetween. The pads 112 are formed on the upper surface of the redistribution layer 106. The pads 112 are preferably arranged in full grid. That is, it is preferred to arrange the pads 112 over almost all of the upper surface of the redistribution layer 106. Each pad 112 is covered with an insulating film 113. The solder bump 108 is connected to each pad 112 through an opening formed in the insulating film 113. The solder bump 108 functions as an external electrode terminal of the semiconductor device 1.

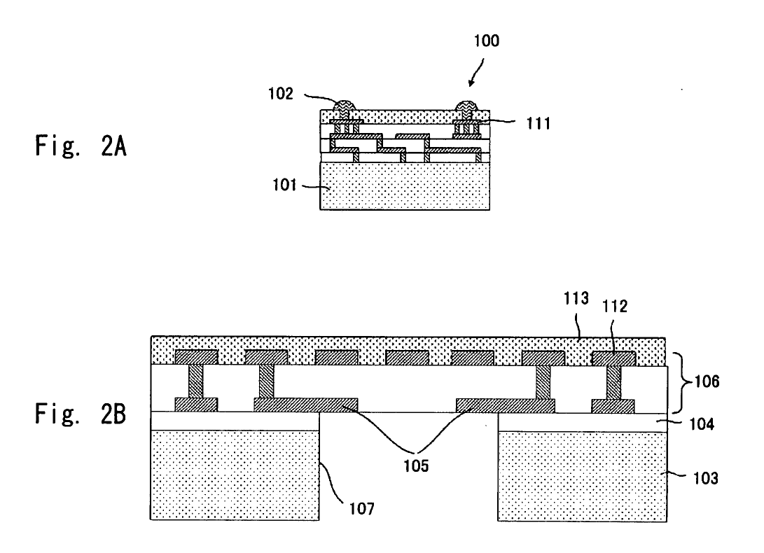

Referring to FIGS. 2A and 2B, a method of manufacturing the semiconductor device 1 according to the first embodiment of the present invention is described next by way of example. First, the semiconductor chip 100 shown in FIG. 2A and the silicon wafer 103 having the redistribution layer 106 formed thereon shown in FIG. 2B are prepared.

The semiconductor chip 100 includes an active region including a transistor, a resistive element, and/or a capacitive element, and a peripheral region including a bonding pad and/or an ESD (electrostatic discharge) protection element. The active region is formed on the silicon wafer 101, and the peripheral region is further formed thereon. In the peripheral region, the bonding pad 111 is formed, and the solder bump 102 is formed on the bonding pad 111. The bonding pad 111 has a size of, for example, about several tens of μm to 100 μm square. A pitch of the bonding pads 111 is also about several tens of μm to 100 μm square. The semiconductor chip 100 is in a wafer state until a step of forming a microbump (solder bump 102), and then, the chip is diced into small pieces. Thus, the semiconductor chip 100 of FIG. 2A is completed.

On the other hand, the silicon wafer 103 having the redistribution layer 106 formed thereon as shown in FIG. 2B is produced as follows. First, the silicon wafer 103 is prepared. No active element is formed on the silicon wafer 103. After the formation of the insulating film 104 grown on the upper surface of the silicon wafer 103, the redistribution layer 106 is formed only through a general line formation step, not through a step of forming the active region and peripheral region. At this point, the solder bump 108 has not formed yet.

Next, the silicon wafer 103 is partially removed to expose the rear surface of the redistribution layer 106 (the surface on the silicon wafer 103 side). To be specific, under such conditions that the redistribution layer 106 is formed, the silicon wafer 103 is etched selectively from its rear surface to form the opening 107 for embedding the semiconductor chip 100. The opening 107 passes through the silicon wafer 103 and extends up to the bottom line of the redistribution layer 106. At this time, the redistribution layer 106 is designed such that the land 105 to be connected with the solder bump 102 of the semiconductor chip 100 is exposed to the opening 107. The silicon wafer 103 having the redistribution layer 106 formed thereon as shown in FIG. 2B is completed in this way.

Next, the semiconductor chip 100 is placed in the space (opening 107) that is formed by removing a part of the silicon wafer 103. At this time, it is necessary to perform positioning such that the solder bump 102 of the semiconductor chip 100 comes into contact with the land 105 of the silicon wafer 103, but a register pattern (not shown) is formed in the bottom layer of the redistribution layer 106 beforehand to thereby easily bring the solder bump 102 and the land 105 into contact with each other without displacement. After that, heat treatment is carried out for alloying the solder bump 102 and the land 105. As a result, the semiconductor chip 100 is connected to the land 105 with the solder bump 102, and the semiconductor chip 100 and the redistribution layer 106 are electrically connected together. Incidentally, a gap between the semiconductor chip 100 and the silicon wafer 103 is desirably sealed with an insulating resin sealant (not shown) used in a general semiconductor manufacturing process, such as polyimide.

Subsequently, the rear surface of the silicon wafer 103 is polished and leveled. After that, the solder bump 108 is connected to the pad 112 of the redistribution layer 106. The solder bump 108 may be formed as a solder ball or formed by a printing method with a solder paste. After the formation of the solder bump 108, dicing is optionally performed. Through the above steps, the semiconductor device 1 of FIG. 1 is completed.

To describe beneficial effects of this embodiment, according to this embodiment, the redistribution layer 106 which is formed with the silicon wafer 103 used as a supporting substrate can be obtained not through wafer fabrication process for forming the active region. Thus, the device can be manufactured at lower cost than that of existing W-CSPs. Further, the device can be manufactured with a general silicon wafer production line alone, so any special supporting substrate or reinforcing frame is unnecessary. This contributes to further reduction in manufacturing cost. Thus, a semiconductor device and a method of manufacturing the semiconductor device, which can save a manufacturing cost, are realized.

Incidentally, a LSI design rule gets finer every year. However, not all packaging techniques on the set maker side follow this tendency. In the future, there is a possibility that although new functions are added and a chip size is reduced, the number of pins is increased in accordance with the added functions, resulting in an increase in package size. A W-CSP capable of arraying functional pins in full grid on a mounting surface would be an effective measure therefore, but as described above, a problem of increasing a cost in proportion to the number of pins remains to be solved. This embodiment can save a cost and would increase in importance in the future since a gap might increase between a finer LSI design rule and a mounting pitch.

### Second Embodiment

A semiconductor device according to a second embodiment of the present invention comprises: a redistribution layer including a plurality of pads to be connected with an external electrode terminal and a plurality of redistribution lines to be connected with the pads, the pads being exposed at an upper surface; a semiconductor chip connected to the redistribution lines at a rear surface as the opposite surface to the pads of the redistribution layer; and a supporting substrate which is provided on the rear surface of the redistribution layer and to which the semiconductor chip is embedded.

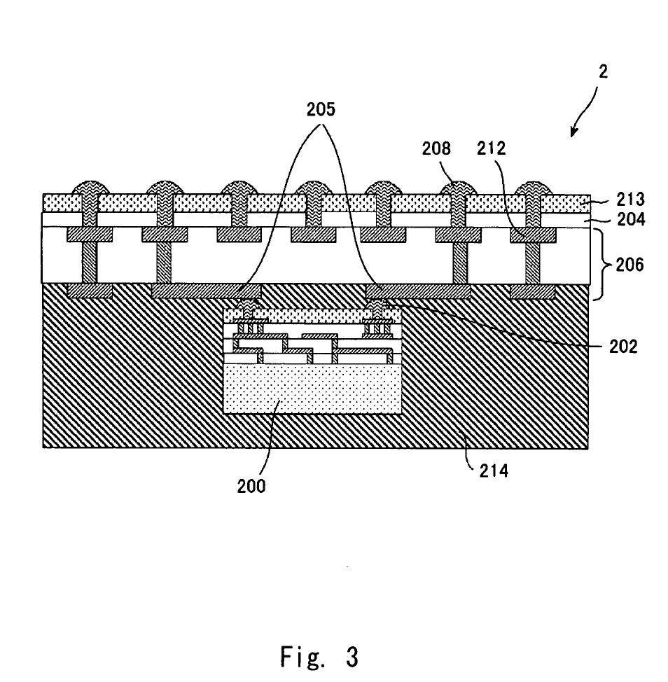

FIG. 3 is a sectional view of a semiconductor device according to a second embodiment of the present invention. A semiconductor device 2 includes a redistribution layer 206, and a semiconductor chip 200 connected to a land 205 of the redistribution layer 206. The configuration of the semiconductor chip 200 is the same as the semiconductor chip 100 of FIG. 2A. In the first embodiment, the semiconductor chip 100 is placed in the opening 107 formed in the silicon wafer 103 (see FIG. 1). In contrast, in this embodiment, the semiconductor chip 200 is bonded to the upper surface of the redistribution layer 206 through flip chip bonding. The semiconductor chip 200 is covered with an insulating resin sealant 214. It is preferred that the insulating resin sealant 214 have high rigidity and much larger thickness than the semiconductor chip 200.

At the rear surface of the redistribution layer 206 (the upper surface in FIG. 3), pads 212 are exposed. On the rear surface of the redistribution layer 206, an insulating film 204 and an insulating film 213 are stacked in this order. Solder bumps 208 are connected to the pads 212 through an opening formed in the insulating film 204 and the insulating film 213. The solder bump 208 functions as an external electrode terminal of the semiconductor device 2.

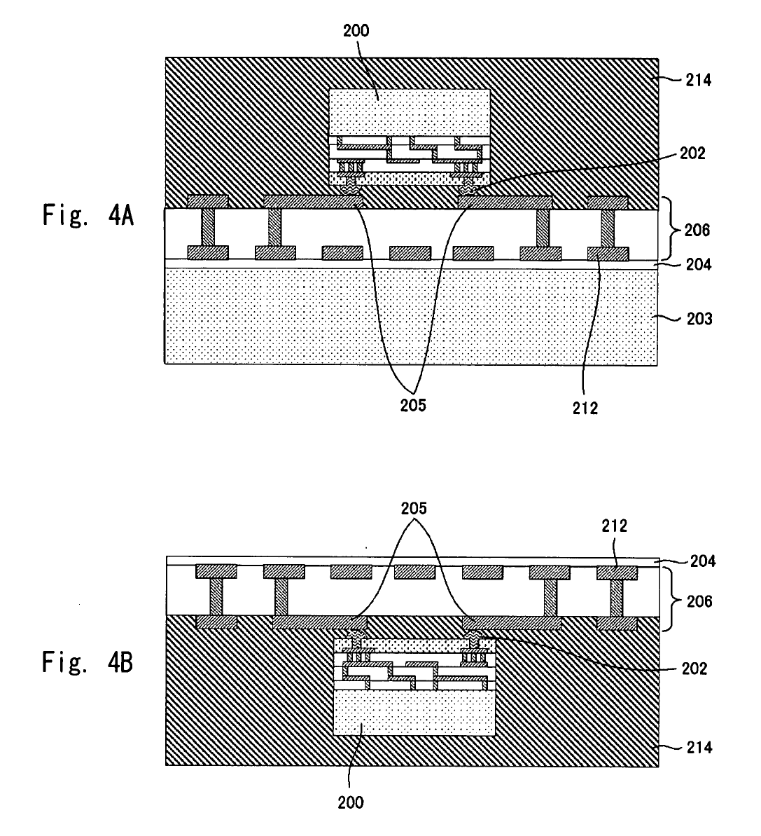

Referring to FIGS. 4A and 4B, a method of manufacturing the semiconductor device according to the second embodiment of the present invention is described next for illustrative purposes. First, the redistribution layer 206 is formed on the silicon wafer 203 with the insulating film 204 interposed therebetween. After that, the semiconductor chip 200 is flip-chip bonded to a redistribution line (land 205) exposed at the upper surface of the redistribution layer 206. Subsequently, the insulating resin sealant 214 is formed over the entire upper surface of the redistribution layer 206 to cover the semiconductor chip 200. A surface of the resin sealant 214 is polished and leveled, if necessary. As a result, the structure of FIG. 4A is completed.

Next, the silicon wafer 203 is completely removed to expose the rear surface of the redistribution layer 206. That is, the silicon wafer 203 is removed by polishing or peeling off to expose the rear surface of the redistribution layer 206. At this time, the insulating resin sealant 214 serves as a supporting substrate. As a result, the structure of FIG. 4B is obtained. After that, the solder bump 208 is formed on the pad 212. To that end, it is necessary to design the device such that the land 205 to be connected with the solder bump 202 of the semiconductor chip 200 is formed on the top of the redistribution layer 206, and the pad 212 to be connected with the solder bump 208 is formed on the bottom of the redistribution layer 206. Then, the insulating resin sealant 214 and the redistribution layer 206 are diced into small semiconductor devices 2.

Beneficial effects of this embodiment are described here. In the first embodiment, it is necessary to form an opening for embedding the semiconductor chip, in the silicon wafer. A position of the redistribution layer formed on the silicon wafer is necessary for positional alignment of the opening. To determine the position, an infrared pattern recognition function should be added to a photoresist exposure device. This increases a facility cost. In contrast, according to this embodiment, the semiconductor chip 200 and the redistribution layer 206 can be connected through general flip chip bonding, so additional special facility is unnecessary. Therefore, a manufacturing cost can be further saved. The other effects of this embodiment are similar to the first embodiment.

The semiconductor device and a method of manufacturing the semiconductor device according to the present invention are not limited to the above embodiments but may be variously modified.

It is apparent that the present invention is not limited to the above embodiment but may be modified and changed without departing from the scope and spirit of the invention.

What is claimed is:

1. A method of manufacturing a semiconductor device including a semiconductor chip, comprising:
forming a redistribution layer including a plurality of pads to be connected with an external electrode terminal and a plurality of redistribution lines to be connected with the pads on a silicon wafer, the pads being exposed;
removing a predetermined portion of the silicon wafer to expose the redistribution lines at the opposite surface to the pads of the redistribution layer;
placing the semiconductor chip in a space formed by removing the predetermined portion of the silicon wafer; and
connecting the semiconductor chip to the redistribution lines exposed at the opposite surface.

2. The method of manufacturing a semiconductor device according to claim 1, wherein the pads are arrayed over almost all of one surface of the redistribution layer.

3. The method of manufacturing a semiconductor device according to claim 1, further comprising:
forming the external electrode terminal to be connected with the pads after connecting the semiconductor chip.

4. The method of manufacturing a semiconductor device according to claim 1, wherein no active element is formed on the silicon wafer.

5. The method of manufacturing a semiconductor device according to claim 1, wherein the semiconductor chip is connected to the redistribution lines of the redistribution layer through a solder bump.

6. The method of manufacturing a semiconductor device according to claim 1, wherein the semiconductor chip includes an active region including at least one of a transistor, a resistive element, and a capacitive element, and a peripheral region including at least one of a bonding pad and an electrostatic discharge protection element.

7. A method of manufacturing a semiconductor device including a semiconductor chip, comprising:
forming a redistribution layer including a plurality of pads to be connected with an external electrode terminal and a plurality of redistribution lines to be connected with the pads on a silicon wafer, the redistribution lines being exposed;
connecting the semiconductor chip to the redistribution lines; and
removing the silicon wafer to expose the pads at the opposite surface to the redistribution lines of the redistribution layer.

8. The method of manufacturing a semiconductor device according to claim 7, further comprising:
forming a resin sealing material on a surface of the redistribution layer where the redistribution lines are connected to the semiconductor chip before removing the silicon wafer.

9. The method of manufacturing a semiconductor device according to claim 7, wherein the pads are arrayed over almost all of the opposite surface of the redistribution layer.

10. The method of manufacturing a semiconductor device according to claim 7, further comprising:
forming the external electrode terminal to be connected with the pads after removing the silicon wafer.

11. The method of manufacturing a semiconductor device according to claim 7, wherein no active element is formed on the silicon wafer.

12. The method of manufacturing a semiconductor device according to claim 7, wherein the semiconductor chip is connected to the redistribution lines of the redistribution layer through a solder bump.

13. The method of manufacturing a semiconductor device according to claim 7, wherein the semiconductor chip includes an active region including at least one of a transistor, a resistive element, and a capacitive element, and a peripheral region including at least one of a bonding pad and an electrostatic discharge protection element.
